(19) United States
(12) Patent Application Publication
(10) Pub. No.: US 2008/0205010 A1
(43) Pub. Date: Aug. 28, 2008

(54) ACTIVE MATRIX BACKPLANES ALLOWING RELAXED ALIGNMENT TOLERANCE

(75) Inventor: Michael A. Haase, St. Paul, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/678,865

(22) Filed: Feb. 26, 2007

(51) Int. Cl. H05K 1/02; H05K 1/03

(52) U.S. Cl. 361/763; 361/749; 361/760; 361/782; 361/783

(57) ABSTRACT

Backplanes for display devices and systems incorporating such backplanes are described. Pixel electrodes are disposed in an array of rows and columns on a substrate. The pixel electrodes may include electrode extensions. Data lines having a substantially constant width are arranged in relation to the pixel electrodes. Enable lines are configured to carry signals that control current flow between the data lines and the pixel electrodes. Each enable line has a substantially constant width and crosses a row of pixel electrodes and electrode extensions. The backplane design may include storage capacitors at the crossings of the enable lines and the pixel electrodes.

### RELATED PATENT DOCUMENT

This patent application is related to commonly owned U.S. patent application identified by Attorney Docket No. 62674US002, entitled “FABRICATION OF BACKPLANES ALLOWING RELAXED ALIGNMENT TOLERANCE,” filed concurrently herewith and incorporated herein by reference.

### TECHNICAL FIELD

The present invention is related to backplanes for display devices and systems incorporating such backplanes.

### BACKGROUND

Active matrix backplanes for liquid crystal and other types of displays are well known. Current display devices typically use a glass substrate with an array of optically active pixels that are selectively controlled to produce viewable images. For example, each pixel may be controlled through signals on the display backplane that are generated by controller circuitry.

Conventional backplane designs require high resolution photolithography processes to form multilayer backplane circuitry. These high-resolution processes require substantial investment in equipment to achieve precise layer-to-layer alignments on substrates that are relatively flat and rigid. It is desirable to form backplane circuitry on substrates that are flexible or stretchable. Backplane layouts that are amenable to fabrication using low-cost roll-to-roll processing methods are also desirable. The present invention fulfils these and other needs, and offers other advantages over the prior art.

### SUMMARY

Embodiments of the present invention are directed to backplanes for display devices and systems incorporating such backplanes. In one embodiment of a display backplane, pixel electrodes are arranged in an array of rows and columns on a substrate. The pixel electrodes include electrode extensions. Data lines having a substantially constant width are arranged in relation to the pixel electrodes. Enable lines are configured to carry signals that control current flow between the data lines and the pixel electrodes. Each enable line has a substantially constant width and crosses a row of pixel electrodes and electrode extensions. The backplane includes storage capacitors at the crossings of the enable lines and the pixel electrodes.

The substrate may comprise a flexible or stretchable material. The substrate may be formed of a polymer.

Alignment of the enable lines and electrode extensions may vary across the backplane. The variation in alignment is related to distortion of the substrate during fabrication. To accommodate the variation in alignment, a length of the electrode extensions may be more than three times a width of the enable lines.

In some embodiments, each electrode extension extends in a direction of a column and along an edge of a major portion of a next pixel electrode in the column.

The backplane may include transistors configured to allow the current flow between the data lines and the pixel electrodes in response to the signals on the enable lines. For example, the transistors may be thin film transistors and/or may comprise ZnO. In one configuration, the enable lines form anodized aluminum gates of the transistors, the data lines form source or drain electrodes of the transistors, and the electrode extensions form the drain or source electrodes of the transistors. In some implementations, the source or drain electrodes of the transistors have a width greater than the width of the enable lines.

A display backplane according to another embodiment includes pixel electrodes having electrode extensions arranged on a substrate. Enable lines are configured to carry signals that control current flow to the pixel electrodes. Each enable line crosses one or more electrode extensions. Each of the electrode extensions has a length greater than about three times a width of the enable line at the crossing of the enable line and the electrode extension.

According to one aspect of the embodiment, storage capacitors are disposed at the crossings of the enable lines and the pixel electrodes.

A display backplane according to yet another embodiment includes one or more rows of pixel electrodes arranged on a substrate. Data lines are arranged substantially perpendicular to the row of pixel electrodes. The backplane includes enable lines having a substantially constant width. Each enable line crosses the pixel electrodes of a row across a major dimension of the pixel electrodes. Transistors are arranged on the display backplane and are configured to allow current flow between the data lines and pixel electrodes.

A display backplane of a further embodiment includes at least one column of pixel electrodes arranged on a substrate. Enable lines are configured to carry signals that control current flow to the pixel electrodes. Each enable line is associated with at least one corresponding pixel electrode of the column of pixel electrodes. Alignment of the enable lines with respect to their corresponding pixel electrodes varies with position along the column of pixel electrodes.

A display backplane according to another embodiment includes pixel electrodes arranged in columns. Each pixel electrode has a major portion and one or more electrode extensions. Each pixel electrode in a column has an electrode extension that extends in the direction of the column along an edge of a major portion of a next pixel electrode in the column. Enable lines cross the electrode extensions and are configured to carry signals that control data flow between data lines and the pixel electrodes.

A display backplane according to a further embodiment includes pixel electrodes having electrode extensions arranged in a matrix on a substrate. Data lines are disposed in relation to the matrix of pixel electrodes. Enable lines cross the pixel electrodes and the data lines. The backplane includes one or more semiconductor regions configured to allow current flow between the data lines and the pixel electrodes. The semiconductor regions may have areas larger than a pitch of the pixel electrodes. Storage capacitors are formed at the crossings of the enable lines and the pixel electrodes.

Another embodiment is directed to a display device. The display device includes a backplane including pixel electrodes having electrode extensions arranged in an array of rows and columns on a substrate. The backplane includes data lines having a substantially constant width. Enable lines are configured to carry signals that control data flow from the data lines to the pixel electrodes. Each enable line has a substantially constant width and crosses a row of pixel electrodes and electrode extensions. Storage capacitors are disposed at the crossings of the enable lines and the pixel electrodes. The display device also includes pixels comprising an optically active material which are coupled to the pixel electrodes.

According to various aspects, the optically active material may comprise a liquid crystal material, an electrochromic material, or an electrophoretic material. In some implementations, the display device is a reflective display device. In some arrangements, the pixels may be color pixels and a common enable line crosses pixel electrodes of like color pixels. In some implementations, a common data line is associated with pixel electrodes of like color pixels.

The above summary of the present invention is not intended to describe each embodiment or every implementation of the present invention. Advantages and attainments, together with a more complete understanding of the invention, will become apparent and appreciated by referring to the following detailed description and claims taken in conjunction with the accompanying drawings.

### DESCRIPTION OF THE DRAWINGS

FIG. 1 is a block diagram of a system that incorporates a display having a backplane in accordance with embodiments of the present invention;

FIGS. 2 illustrates an expanded view of various layers that may be used to form a display in accordance with some embodiments;

FIGS. 3A-3C show portions of backplane layouts including one partial column of a matrix of pixel electrodes and corresponding data and enable lines formed on a substrate in accordance with embodiments of the invention;

FIG. 4 illustrates an alignment tolerance aspect of the backplane layouts of the present invention;

FIG. 5 illustrates a section of a backplane layout in accordance with an embodiment of the invention;

FIG. 6 illustrates a portion of a backplane layout using an unpatterned semiconductor layer in accordance with embodiments of the invention;

FIG. 7 illustrates a backplane useful for a color display with subpixel electrodes arrayed in adjacent columns in accordance with embodiments of the invention;

FIG. 8 illustrates a backplane for a color display with subpixel electrodes arrayed in adjacent rows in accordance with embodiments of the invention; and

FIG. 9 is a diagram illustrating a process by which display backplane may be fabricated in a roll-to-roll process in accordance with embodiments of the invention.

While the invention is amenable to various modifications and alternative forms, specifics thereof have been shown by way of example in the drawings and will be described in detail. It is to be understood, however, that the intention is not to limit the invention to the particular embodiments described. On the contrary, the intention is to cover all modifications, equivalents, and alternatives falling within the scope of the invention as defined by the appended claims.

### DETAILED DESCRIPTION

In the following description of the illustrated embodiments, reference is made to the accompanying drawings that form a part hereof, and in which are shown by way of illustration, various embodiments in which the invention may be practiced. It is to be understood that the embodiments may be utilized and structural changes may be made without departing from the scope of the present invention.

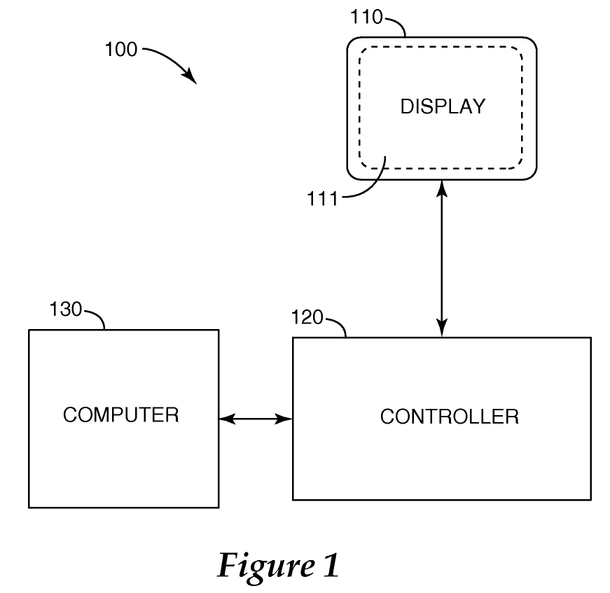

Embodiments of the present invention are directed to display backplanes and to displays and systems incorporating these display backplanes. FIG. 1 is a block diagram of a system 100 that incorporates a backplane 111 in accordance with embodiments of the present invention. A display 110 using a backplane 111 of the present invention employs optically active material arranged in a matrix of pixels. The optically active material, which may include, for example, liquid crystals, electrochromic or electrophoretic material, is coupled through a backplane 111 to a controller 120 that generates signals for selectively energizing the optically active material. The generated signals allow for presentation of information on the display via the optically active material. In a typical application, the display 110 and controller electronics 120 provide an output device for a data source, such as a computer 130.

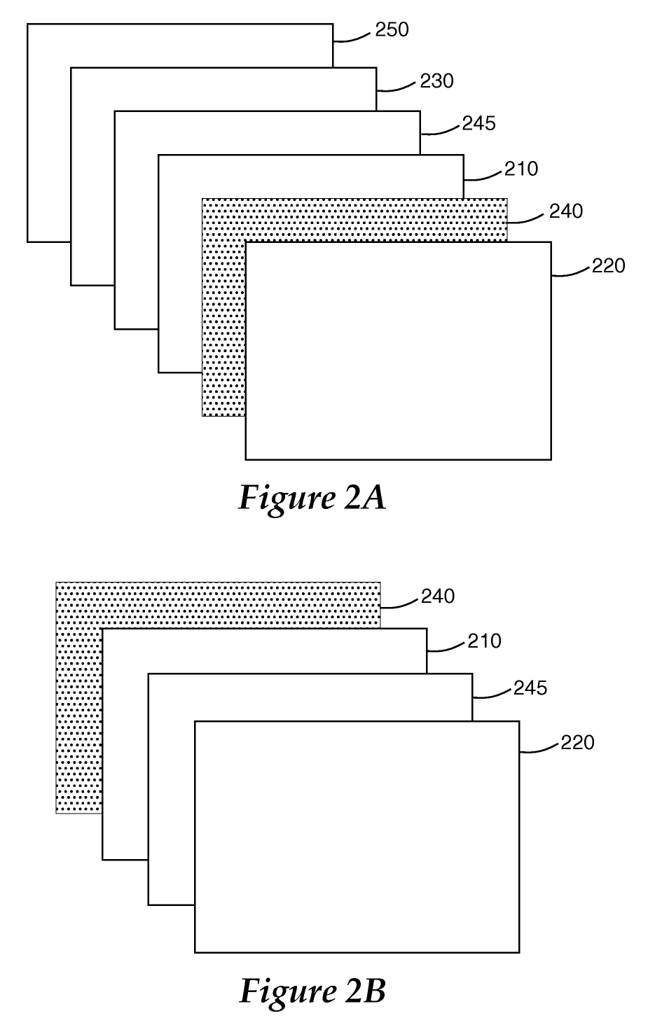

Backplanes in accordance with embodiments of the present invention are used to make flat panel displays that include various material layers. FIG. 2A illustrates an expanded view of layers that may be used to form a display in accordance with some embodiments. In this particular example, the display is illustrated as a flat panel reflective display incorporating liquid crystals as the optically active material. Alternatively, the optically active material may comprise an electrochromic or electrophoretic material. A matrix of optically active pixels 210 is sandwiched between a common electrode layer 245 and a backplane 240. Filters 220, 230 polarize light as it enters and leaves the display.

Electrical signals developed by a controller (not shown in FIG. 2) and delivered via pixel electrodes on the backplane 240 produce an electric field across the liquid crystal pixels causing a change in the orientation or the crystals. The backplane 240 includes enable lines and intersecting data lines. The enable lines are used to multiplex data signals generated by the controller to energize selected pixels. Multiplexed signals reduce the number of data lines needed between the backplane and controller. The data signals control the degree of rotation of the liquid crystals in each pixel. The amount of light allowed to pass through a pixel varies with the degree of rotation of the liquid crystals. A reflective layer 250 may be used to reflect the light entering the display back to the viewer.

FIG. 2B illustrates an alternative configuration for a reflective display device. In this configuration, the backplane 240 is behind the pixel layer 210 allowing the backplane 240 to be made of optically opaque and possibly optically reflective materials.

Backplanes for electronic displays may be manufactured using a sequence of photolithographic and deposition steps requiring alignment of features formed in one processing step with respect to features formed in a previous processing step. Conventional designs involve high-resolution photolithography processes and precise layer-to-layer alignments. These designs typically require substantial investment in equipment and are only successful when using rigid substrates that are relatively flat, such as substrates of glass or other similar materials. The manufacturing processes for these legacy designs typically use at least 5 photolithography steps. The processes and requirements of previous designs are less successful when making backplanes on flexible, stretchable substrates, especially when the substrate is a polymer. In particular, polymer substrates may be prone to shrinkage or expansion due to thermal processing, and/or to absorption or desorption of water or other solvents, making layer-to-layer alignment difficult for conventional designs. Furthermore, previous designs are not generally amenable to manufacture using high-speed, roll-to-roll processes.

The backplane layouts in accordance with embodiments of the present invention provide various advantages over legacy designs. These backplane designs are particularly useful for active matrix thin film transistor backplanes. The designs may be used in conjunction with any optically active display medium that is voltage-controlled, requiring little current. A non-limiting list of display media that may be employed includes all forms of liquid crystals (nematic, twisted nematic, super-twisted nematic, polymer-dispersed, ferroelectride, and cholesteric), as well as alternate media including electrophoretics (e.g., “Electronic Paper” from E Ink Corporation, Cambridge, Mass.) and electrochromics.

Backplane layouts described in accordance with various embodiments can be manufactured using a reduced number of photolithography steps (e.g., about 2 or 3 steps) as compared with previous backplane designs. The need for fewer steps simplifies manufacturing and reduces cost. The backplane layouts presented herein allow for relaxed alignment tolerances between subsequent photolithographic patterns making these layouts particularly well suited to roll-to-roll manufacturing. Furthermore, the layouts described in accordance with various embodiments are particularly useful for depositing backplanes on flexible substrates, such as polymer substrates.

The backplane layouts of the present invention are also particularly effective when used for reflective displays. The pixel electrodes can be opaque, allowing the pixel electrodes and the transistor source/drain electrodes to be formed of the same metal layer, as opposed to using a transparent pixel electrode.

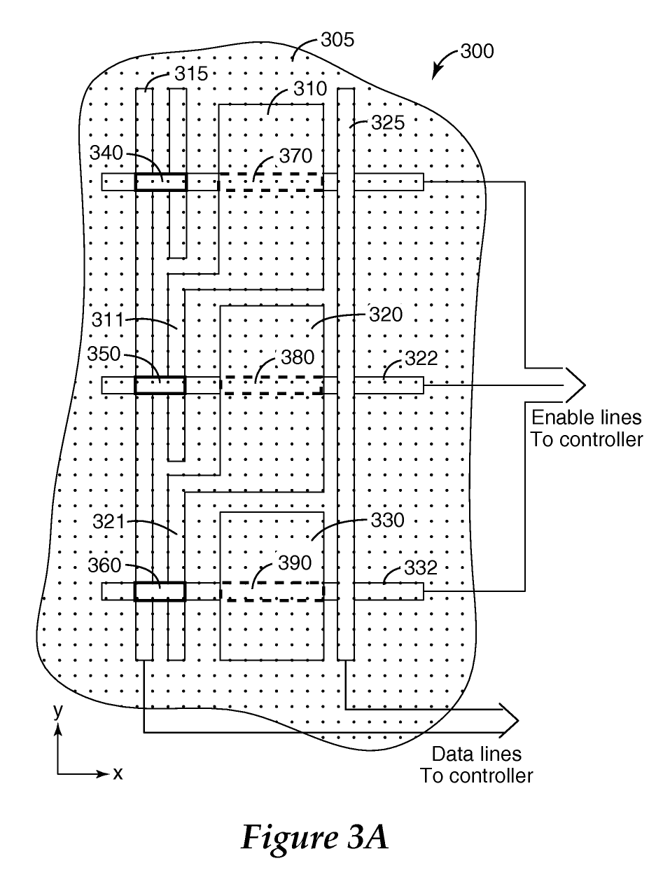

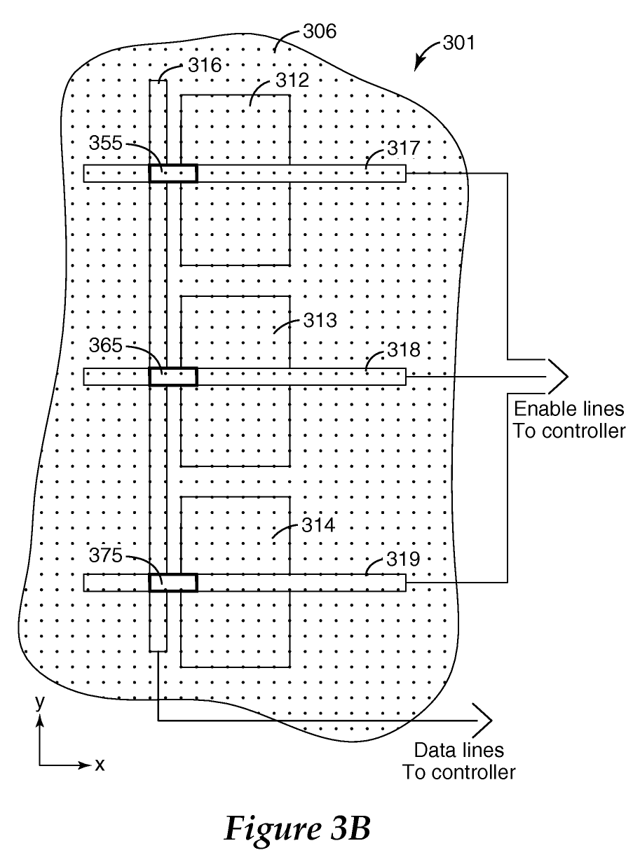

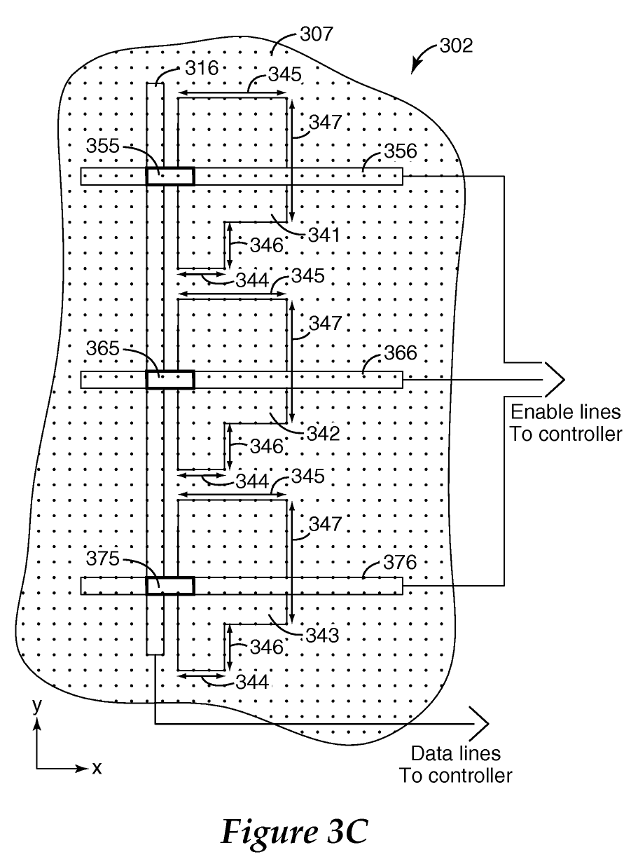

FIGS. 3A-3C, and 4-8 illustrate sections of backplane layouts in accordance with various embodiments. The size of a backplane may vary to accommodate different display sizes by repeating the pixel electrode configurations illustrated in FIGS. 3A-3C and 4-8 for the desired number of pixel electrodes. As will be appreciated by those skilled in the art, a complete backplane may include multiple data lines and multiple enable lines typically substantially orthogonal to the data lines along with multiple pixel electrodes arranged in a matrix configuration, although other orientations may be used. A transistor or other switching element may be used in conjunction with each pixel electrode of the backplane. Some embodiments include storage capacitors associated with the pixel electrodes.

The sectional view of the backplane 300 illustrated in FIG. 3A shows a portion of a backplane layout including one partial column of a matrix of pixel electrodes 310, 320, 330 formed on the substrate 305. The substrate 305 may be flexible or stretchable and/or may be formed of a polymer. The backplane 300 includes data lines 315, 325 that carry data signals to the pixel electrodes 310, 320, 330. The data signals convey information to be displayed via the display pixels (not shown). In some implementations, the data lines 315, 325 are “branchless” metal lines. In some implementations, the data lines may be branchless along some portions of the data lines, such as at the crossing of the data lines 315, 325 and the enable lines 322, 332. The term branchless denotes a substantially straight line having a substantially constant line width.

Connections between a data line 315 and pixel electrodes 310, 320 are multiplexed using enable lines 322, 332. The enable lines 322, 332 may be metallic lines that are branchless along the entire length of the enable lines 322, 332. In alternate embodiments, the enable lines may be branchless along certain portions of the enable lines, such as at the intersections of the data lines and the enable lines, but may have variable widths, i.e., branches elsewhere, such as a larger width in the vicinity of the storage capacitors. Transistors 355, 365, 375 control data flow between data line 316 and pixel electrodes 341, 342, 343.

Each pixel electrode 310, 320 includes an electrode extension 311, 321. As illustrated in FIG. 3A, the electrode extension 311 of a pixel electrode 310 may extend in the direction of a column (in the y direction as indicated in FIG. 3A) along at least a portion of an edge of the next pixel electrode 320 in the column.

During deposition of the various backplane layers on a flexible substrate web, the substrate may distort, causing misalignment to occur between backplane layers. In one configuration, the pixel electrode columns are arranged in the cross-web direction, the y direction) and the rows are arranged in the down-web direction (x direction). Distortion of the substrate in the cross-web direction causes variation in alignment along the column of pixel electrodes between the pixel electrodes or electrode extensions and the enable lines. For example, an enable line at one position, y₁, of a column of pixel electrodes may be oriented near the top of an electrode extension. At another position, y₂, along the same column, an enable line may be oriented near the bottom of an electrode extension. The variation in alignment along the column is related to the distortion of the backplane substrate during fabrication. The variation in alignment across the backplane may be greater than about 5 microns, for example.

The alignment tolerance between the enable lines and the electrode extensions is related to the length of the electrode extensions 311, 321 and the width of the enable lines 322, 332. The length of the electrode extensions 311, 321 is greater than the width of the enable lines 322, 332 to achieve a desired amount of alignment tolerance between the enable lines 322, 332 and the electrode extensions 311, 321. For example, in one embodiment, the length of the electrode extensions 311, 321 is greater than three times the width of the enable lines 322, 332. In other embodiments, the length of the electrode extensions 311, 312 is 4 or more times the width of the enable lines 322, 332.

Transistor switches 350, 360 allow current flow between a data line 315 and a pixel electrode 310, 320 via electrode extensions 311, 321. The enable lines 322, 332, which may comprise anodized aluminum, for example, form gate electrodes of transistors 350, 360. The transistors 340, 350, 360 function as switches under the control of the enable lines 322, 332 to selectively couple the data line 315 and the pixel electrodes 320, 330. When switched on, the transistors 350, 360 allow current flow between the data line 315 and the pixel electrodes 310, 320 responsive to a signal on an enable line 322, 332. The direction of current flow within each transistor 350, 360 is substantially parallel to the enable line 322, 332.

For example, in one configuration, the data line 315 forms the source (or drain) electrodes of the transistors 350, 360 and the electrode extensions 311, 321 form the drain (or source) electrodes of the transistors 350, 360. The source or drain electrodes may be the same width (i.e., extent in the direction orthogonal to the enable line) as the enable line or have widths greater than the width of the enable line. When a signal on an enable line 322, 332 energizes the gate of a transistor 350, 360, a connection is made through the transistor 350, 360 between the data line 315 and pixel electrode 320, 330. Pixel storage capacitors 370, 380, 390 may be disposed where the enable lines 322, 332 and pixel electrodes 320, 330 cross.

The sectional view of the backplane 301 illustrated in FIG. 3B includes one partial column of a matrix of pixel electrodes 312, 313, 314 in accordance with another embodiment. This particular embodiment does not include electrode extensions or storage capacitors. Pixel electrodes 312, 313, 314 are arranged in a matrix on a substrate 306, which may be a flexible, polymeric substrate, for example. Enable lines 317, 318, 319 are arranged substantially orthogonal to data lines 316 and the column of pixel electrodes 312, 313, 314. The data line 316, and/or the enable lines 317, 318, 319 may be branchless or may be branchless along certain portions. Transistors 355, 365, 375 allow current to flow between the data line 316 and the pixel electrodes 312, 313, 314 responsive to signals on the enable lines 317, 318, 319.

The pixel electrodes 312, 313, 314 in FIG. 3B are illustrated as rectangles, although the pixel electrodes may be formed in other shapes. For example, as illustrated in the backplane 302 of FIG. 3C, pixel electrodes 341, 342, 343 are arranged on a substrate 307. The pixel electrodes 341, 342, 343 may comprise a shape having one or more major dimensions 345, 347 and one or more minor dimensions 344, 346. The enable lines 356, 366, 376 cross a major dimension 345, 347 of the pixel electrodes 341, 342, 343.

A display backplane, including enable lines, data lines, pixel electrodes, transistors and storage capacitors, may be formed as a multilayer structure on the surface of a substrate. For example, in a first processing step, the enable lines and capacitor electrodes may be formed by depositing an opaque or transparent conductor comprising materials such as aluminum, chromium, molybdenum, tantalum, titanium, copper, or alloys thereof, tin oxide, indium tin oxide, and/or doped zinc oxide on the substrate followed by standard photolithography and etching. Portions of the enable lines form the gate electrodes of the switching transistors. A gate insulation film is formed over the transistor gate electrodes. For example, the gate insulator may be formed by anodization of the enable lines. To anodize the enable lines, it is convenient to form the enable lines with a common bus that connects them on one end. The bus connection is used to bias the lines during anodization. Subsequently, the bus connection is removed by etching or cutting away that portion of the substrate.

A thin semiconductor film, e.g., ZnO or a—SiH, is deposited over the gate insulator, such as by sputtering, chemical vapor deposition, vacuum evaporation, or other suitable deposition processes. In certain embodiments, the semiconductor is patterned in regions of the gate electrode, but the pattern need not be confined to the area near the gate electrode or the area near the enable lines. For example, the semiconductor may be patterned in larger regions over the gate electrodes or the semiconductor may be substantially unpatterned, resulting in a layer of semiconductor material over a majority of the backplane. The pixel electrodes and data lines may be formed in a single step by sputtering a metal layer over the semiconductor layer and patterned by photolithography etching or liftoff.

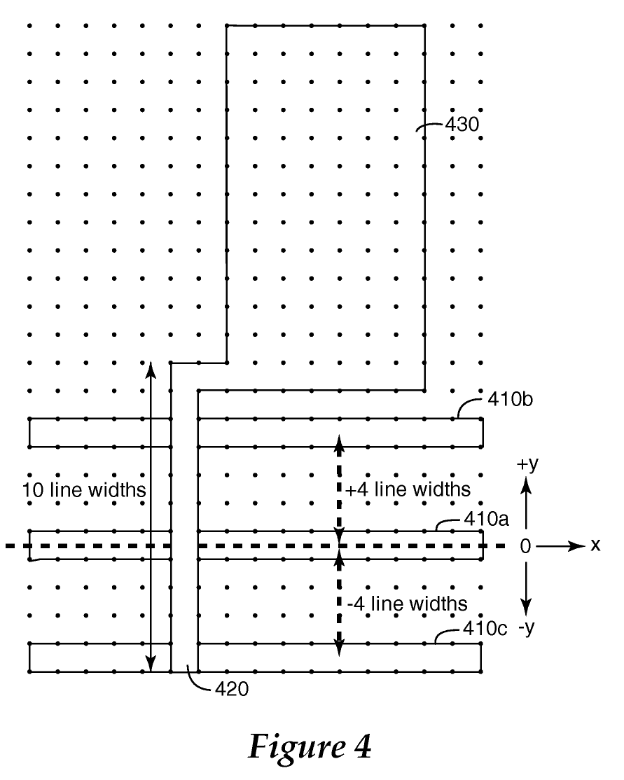

The backplane layouts illustrated in FIGS. 3A-3C provide for relaxed layer-to-layer alignment tolerances when compared to previous backplane designs. The alignment tolerance in the cross web direction (y direction) of the backplane designs illustrated in FIGS. 3B and 3C is related to the length of the pixel electrodes in the direction of the column and the width of the enable lines. The alignment tolerance in the cross web direction of the backplane design illustrated in FIG. 3A is related to the length of the electrode extensions and the width of the enable lines. The alignment tolerance aspect of the invention is best understood with reference to FIG. 4. The backplane layout illustrated in FIG. 4 depicts a backplane having a pixel pitch that is 12 times the minimum line width, an aperture ratio of 55%, and an alignment tolerance of +/−4 line widths, i.e., 33% of the pixel pitch.

In FIG. 4, the length of the electrode extension 420 is 10 times the width of an enable line 410. The pixel electrode/electrode extension layer only needs to be aligned with the enable line layer to within +/−4 enable line widths. The length of the electrode extension 420 may be selected to accommodate misregistration between backplane layers that may be caused by fabrication on a flexible substrate, for example. In one configuration, the enable line has a width of about 25 microns and the electrode extensions extend about 100 microns on either side of the enable line.

For example, FIG. 4 shows a first alignment scenario with enable line 410a positioned near the middle of the electrode extension 420 in a position designated as a reference position. FIG. 4 illustrates a second alignment scenario corresponding to a maximum misalignment of the pixel electrode/electrode extension 430/420 with respect to the enable line 410b in the positive y direction. The enable line 410b is positioned near the top of the electrode extension 420 which is nearest the pixel electrode 430. A third alignment scenario corresponds to the maximum misalignment of the pixel electrode/electrode extension 430/420 with respect to the enable line 410c in the negative y direction. In the third alignment scenario, the enable line 410c is positioned near the bottom of the electrode extension 420.

FIG. 4 illustrates an electrode extension having a length that is 10 times the width of the enable line, although electrode extensions that are longer or shorter in relation to the width of the enable line may be used. For example, in some embodiments, the electrode extensions may be greater that about three times the width of the enable lines.

The alignment tolerance for a backplane design generally depends on the amount of distortion of the backplane substrate during the fabrication process. For example, a backplane formed on a very rigid substrate may be fabricated with a smaller alignment tolerance than a backplane formed on a flexible substrate. For example, given a backplane having N rows of pixels of height H and enable lines of width W, the length of the pixel extension, L, may be determined according to the equation:

L>kNH+W [1]

where k is a dimensionless constant that depends on substrate material and thickness and is related to the distortion of the substrate due to various processes to which the backplane substrate is exposed during fabrication.

Note that the value of NH is related to the height of the display. Elastic and inelastic stretching of the substrate web during processing can be a particularly significant factor in the distortion, especially in the down-web direction. For that reason, it is preferable to align the rows in the down web direction since the designs described herein require minimal alignment along the rows. The designs described herein typically use a value of k larger than about 4×10⁻⁴. Generally, if a polymeric substrate is used a value of k larger than about 1.0×10⁻⁴ should be used.

As previously mentioned, one aspect of the design illustrated in FIG. 4 is that even for a small pixel pitch of 12 line widths (e.g., about 300 μm) the source-drain layer need only be aligned to the gate to within +/−4 line widths (e.g., about 100 μm, or 33% of the pixel pitch) and yet a 55% aperture is achieved. In the backplane layout illustrated in FIG. 3A, for example, the storage capacitance is 6 times the parasitic gate to source capacitance, Cₛₜ=6 C_{gs}.

Advantageous features of the above-described backplane layouts include enable lines and transistor gate electrodes that may be branchless metal lines that require little to no alignment in the x dimension along the rows. In addition, the source and drain electrodes of the transistors are much wider in the direction perpendicular to the current flow than the gate enable line itself, thus relaxing the alignment tolerance in the direction perpendicular to the current flow. These features are achieved with minimal degradation of the resolution and performance of the display that incorporates the backplane.

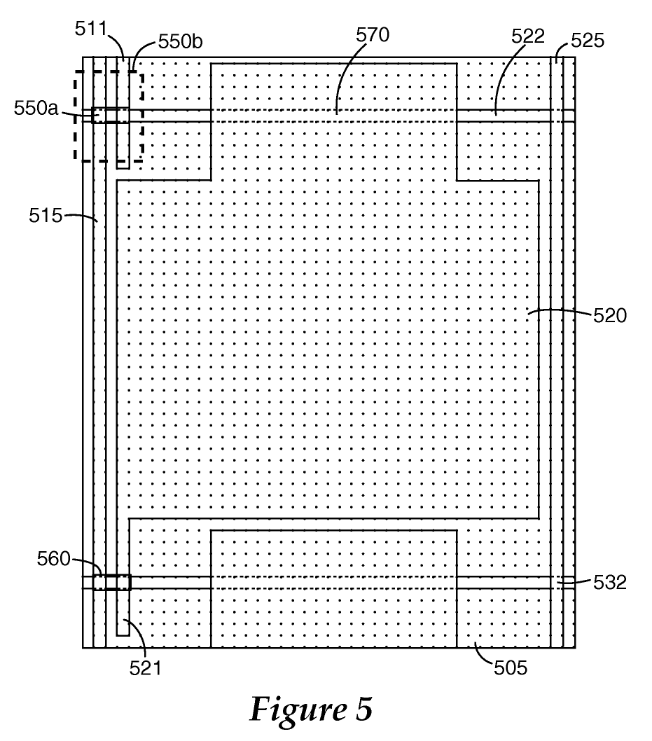

The pixel pitch, aperture ratio, and alignment tolerance of backplane layouts in accordance with embodiments of the invention may vary. FIG. 5 illustrates a section of a backplane layout in accordance with another embodiment. The plan view illustrated in FIG. 5 shows a pixel electrode 520 disposed between data lines 515, 525 and enable lines 522, 532 on a substrate 505. The pixel electrode 520 includes an electrode extension 521. A portion of an adjacent electrode extension 511 is also shown. The backplane layout illustrated in FIG. 5 includes a transistor switch 560 and storage capacitor 570 for the pixel electrode 520.

The backplane layout of FIG. 5 has a different fraction of pixel pitch to minimum line width when compared to the embodiment illustrated in FIG. 3A. In the backplane layouts illustrated in FIGS. 3A and 5, the alignment tolerance is +/−4 line widths. However, the layout of FIG. 5 has a pixel pitch of about 40 times the minimum line width and an aperture ratio of about 81%. The storage capacitance is 22 times the parasitic gate to source capacitance, Cₛₜ=22 C_{gs} for this design.

The semiconductor may be patterned proximate the enable lines to form the switching transistors, as illustrated, for example, in FIG. 5. Patterning the semiconductor is performed at the cost of a photolithography step that protects the transistor regions during etching. In some implementations, as illustrated in FIGS. 5, the semiconductor 550a of the transistor may be patterned so that the semiconductor of the transistor 550a does not extend substantially beyond the area associated with a portion of the enable line 522 between data line 515 and electrode extension 511. In an alternative configuration, the semiconductor 550b forming the transistor may extend beyond this area allowing increased alignment tolerance. For example, in one embodiment, the semiconductor 550b may be disposed in regions between the data lines and associated electrode extensions, and enable lines. In one embodiment, the semiconductor region may be greater than the column pitch so that the semiconductor material extends between the data lines 515, 525.

In yet a further embodiment, the semiconductor may be substantially unpatterned, resulting in a layer of semiconductor material over a majority of the backplane substrate 505. In such embodiments, semiconductor material not controlled by the enable (gate) lines preferably has a conductivity sufficiently low to maintain a useful charge on the pixel electrode until the pixel electrode voltage is refreshed.

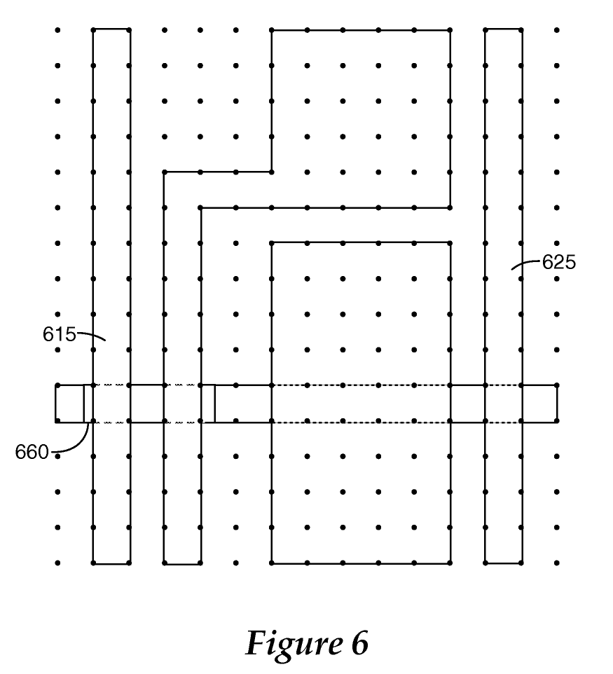

If the semiconductor extends between data lines, voltages on the data lines may be adjusted to compensate for crosstalk between the data lines. FIG. 6 shows a larger detail of a layout similar to the layout illustrated in FIG. 3A. For example, referring to FIG. 6, if semiconductor exists proximate to the row enable line (gate) in the regions to the right of the transistor 660, a conducting channel forms when that row is enabled that may extend from data line 615 all the way to data line 625 on the right. A portion of that conduction channel is shorted by the pixel electrode corresponding to the next (lower) row. Assuming the transistor 660 is operated in the linear mode, the steady-state pixel voltage can be estimated to be the result of a simple voltage divider:

Vₚᵢₓₑₗ=(1−x)V_{col1}+xV_{col2}, [2]

where V_{col 1} and V_{col2} are the data voltages on data line 615 (on the left) and data line 625 (on the right) and x=0.25 represents the amount of crosstalk calculated from the geometry of FIG. 6.

If the semiconductor is unpatterned in the design of FIG. 5, because of the larger distance between data lines, the crosstalk is much less, x=0.06. The resultant effect is to slightly blur the displayed image.

Adjusting the applied data line voltages to compensate can reduce this effect. For example, for any data line i,

Vᵢ^{pixel}+(1−x)Vᵢ+xV_{i +1}, x<<1, [3]

where x represents the amount of crosstalk.

A compensated data line voltage is:

V_{i =[V}ᵢ^{pixel}−xVᵢ₊₁^{pixel}]/(1−x), [4]

where Vᵢ^{pixel} is the desired voltage on the pixel electrode for data line i.

In some embodiments, a portion of each pixel electrode overlaps the row-enable (gate) line of an adjacent (previous) row to form a storage capacitor. If the semiconductor is not patterned, the pixel electrode voltage is altered when an adjacent enable line is energized, because conducting channels are formed in the semiconductor between the pixel electrode and the data lines on either side of it. However, this effect does not result in a significant visible flicker in the display if the rows are scanned in the correct order. That is, after the pixel is altered, the voltage is immediately set to the correct voltage for the next frame if the rows are scanned top to bottom for the orientation shown in FIGS. 3A and 6, for example.

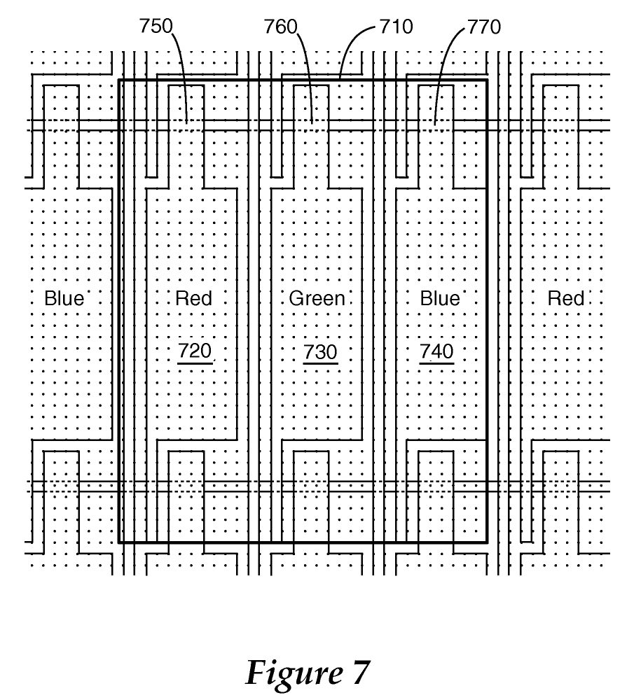

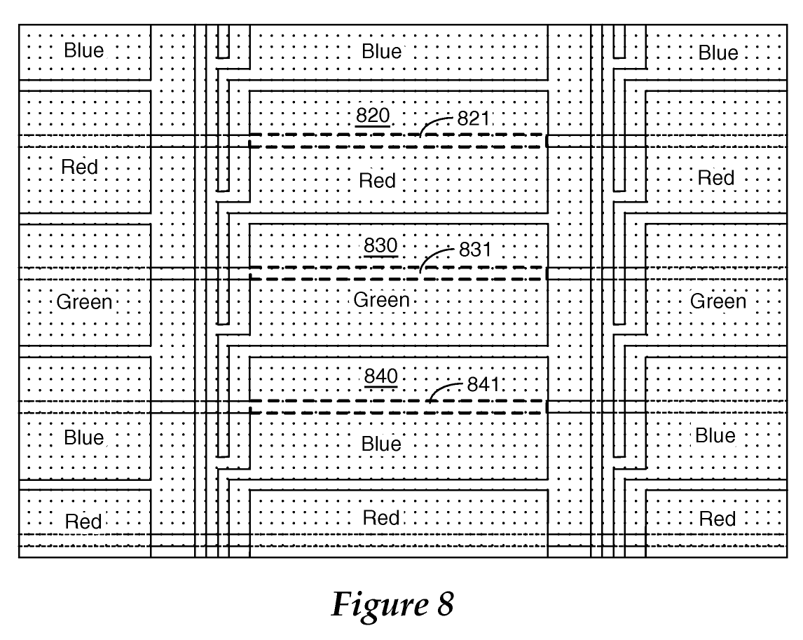

FIGS. 7 and 8 illustrate designs useful for making backplanes for color displays. Each pixel requires a group 710 of color subpixel electrodes. As illustrated in FIG. 7, the subpixels 720, 730, 740 for each color (typically red, green, blue) may be arranged in adjacent columns. In such a design, compensation for crosstalk between columns improves color accuracy (since adjacent columns represent different colors). FIG. 7 illustrates one design for a backplane for a color display. In this design, full color pitch is about 36 times the minimum line width. Red 720, green 730, and blue 740 subpixel colors may be achieved using color filters. The design may include storage capacitors 750, 760, 770. The aperture ratio is about 64% and the storage capacitance is about 4 times the gate to source capacitance, Cₛₜ=4 C_{gs}, for this design.

In an alternative embodiment, illustrated in FIG. 8, color subpixels 820, 830, 840 may be arrayed in adjacent rows. This design allows for larger storage capacitors 821, 831, 841. Crosstalk between columns has less effect on color accuracy, since voltages on adjacent columns represent the same color (at any given time). In addition, a somewhat larger aperture ratio may be achieved through the use of alternating colors in columns. Such a design would have a lower maximum frame rate, since it has three times as many rows.

The backplane design illustrated in FIG. 8, allows for full color pixel pitch that is about 36 times the minimum line width. The aperture ratio for this design is about 72%, with storage capacitance about 27 times the parasitic gate to source capacitance, Cₛₜ₌27 C_{gs}. The alignment tolerance is about +/−4 line widths.

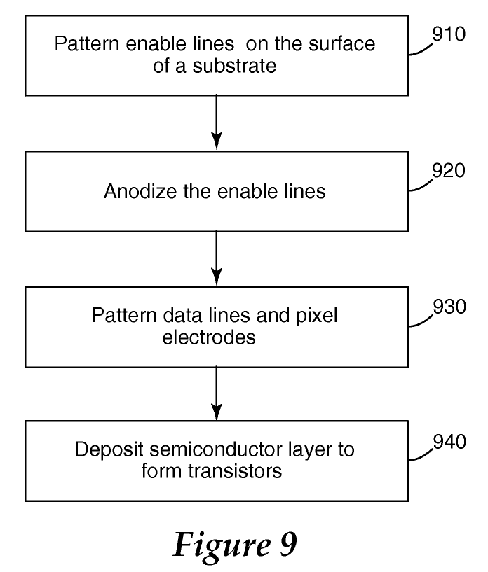

By employing the relaxed alignment tolerance circuit layouts illustrated in the embodiments herein, display backplanes may be fabricated using roll-to-roll manufacturing methods. FIG. 9 illustrates a process by which the display backplanes illustrated in the previous embodiments may be fabricated in a roll to roll process.

The enable lines forming the gate level metal are deposited and patterned 910 on the substrate. The enable lines are anodized 920. The data lines and pixel electrodes forming the source-drain level metal are deposited and patterned 930 on the substrate. A semiconductor layer is deposited 940 and patterned over the metal layers.

In one embodiment, patterning the enable lines and the data lines involves patterning these lines so that they have substantially constant widths. In some configurations, the pixel electrodes are patterned to have electrode extensions. The enable lines cross the pixel electrodes and the electrode extensions. The patterned semiconductor forms transistors wherein the data lines form the source or drain of the transistors and the electrode extensions form the drain or source of the transistors. The enable lines form the transistor gates. Storage capacitors are formed where the enable lines cross the pixel electrodes. In one implementation, the length of the electrode extensions is selected to be greater than about three times the width of the enable lines.

In another configuration, patterning the pixel electrodes involves patterning pixel electrodes without electrode extensions. In this embodiment, patterning the enable lines involves patterning so that the enable lines cross a major dimension of the pixel electrodes. Storage capacitors may not be included in this embodiment.

In one embodiment, distortion of the substrate that occurs during the fabrication process causes alignment of the enable lines with respect to their corresponding pixel electrodes to vary along the columns of pixel electrodes, yet this variance is within the design tolerance

A roll to roll process for forming display backplanes as illustrated by the above embodiments is provided by Example 1.

### EXAMPLE 1

In this example, a roll of polyethylene terephthalate (PET) from DuPont Teijin ST504 is used as a substrate. This substrate is 0.005 inches thick and 12 inches wide. Many other suitable substrates are available for roll-to-roll processes including polyethylene naphthalate (PEN, e.g., DuPont Teijin Q65FA), polyimide, and metal foils, for example steel or aluminum.

Four layers are formed and patterned in this example: Layer 1: Gate Metal; Layer 2: Anodization; Layer 3: Source-Drain Metal; Layer 4: Semiconductor. Each of these steps involves photolithographic patterning. In this example, Asahi UFG-072, a conventional dry-film photoresist is used for each level.

The roll-to-roll photoresist processes common to some of the steps below are as follows:

Apply photoresist

The substrate is unrolled and the photoresist is laminated to it, typically at a temperature of 110 C with a pressure of 30 psi and a web speed of 36 in/min. The substrate is then rolled.

Photoresist Exposure

The substrate is unrolled and stepped frame by frame through a proximity mask aligner and exposed to typically 100 mJ/cm² of broadband ultraviolet light from a high pressure Hg lamp. The substrate is then rolled.

Photoresist Spray Development

The substrate is unrolled and the top surface liner is removed from the photoresist. The substrate and photoresist is passed through a spray developer system using a water solution of 0.71% Na2CO3 and 0.18% NaHCO3 at 70 F. The substrate is rinsed in tap water, followed by a second rinse in deionized water. The substrate is then dried and rolled.

Photoresist Bake

The substrate is unrolled and passed through a 100 C oven for 5 minutes and then rolled.

Photoresist Strip

The unrolled substrate is passed through a spray stripping system using a water solution of 4.6% monoethanolamine at 40 C. The substrate is then rinsed in deionized water and dried.

Gate level metal deposition and patterning process: the gate level metal is vacuum deposited by unrolling and degassing the substrate in a vacuum deposition system. An adhesion promoting layer of about 10 nm of SiO₂ is deposited, followed by 150 nm of Al deposited by DC sputtering. The coated substrate is rolled in vacuum and removed from the deposition system. If the substrate is to be stored before the next process step, it is packaged in an inert atmosphere.

Patterning of the gate level metal is accomplished according to the above common photoresist processes to apply photoresist, expose using the gate level mask, spray develop and bake. The gate level mask defines lines that have a substantially constant width, being about 50 microns wide and extending across the backplane. The enable lines are all connected to a common anodization bus on one end to enable anodization.

The gate level metal is then patterned by unrolling and spray etching the exposed Al with a solution of 45% by weight of KOH in water at 75 F. The substrate is rinsed with water and dried. The photoresist is then stripped using the common photoresist stripping process and the substrate is rolled.

Anodization process: Photoresist is used to protect portions of the gate level metal from anodization. Specifically, bond pads located at one end of the enable lines will be used to connect the enable lines to a controller and so are not anodized. The photoresist is applied according to the above common photoresist processes, exposed during the anodization level mask, and spray developed.

The substrate is subsequently unrolled and passed through a roll-to-roll anodization system. The substrate is biased to 75 V as it is passed through a solution of tartaric acid (3 w/o in DI) mixed with ethylene glycol 1:4 by volume. The electrolyte is titrated to pH 5.5 with NaOH. The dwell time in the electrolyte exceeds 5 min. The substrate is then rinsed, dried and rolled. Subsequently, the substrate is unrolled, stripped of photoresist and rolled.

Source-drain level metal deposition and patterning process: The source-drain metal is deposited by unrolling and degassing the substrate in a vacuum deposition system. An adhesion promoting layer of about 10 nm of SiO₂ is deposited followed by 100 nm of Al deposited by DC sputtering. The coated substrate is rolled in vacuum and removed from the deposition system. If the substrate is to be stored before the next process step, it is packaged in an inert atmosphere.

Patterning for the source-drain level metal is accomplished according to the above common photoresist processes to apply photoresist, expose using the source-drain level mask, spray develop and bake. The source-drain level mask defines data lines and pixel electrodes with electrode extensions. In this example, the electrode extensions are 250 microns long. When this mask is aligned to the substrate, each electrode extension pattern crosses an anodized enable line with an alignment tolerance of +/−100 microns. This enables the backplane to be functionally aligned over a 300 mm×300 mm area, even when fabricated roll-to-roll on a polymer substrate.

The source-drain level metal is then patterned by unrolling and spray etching the exposed Al with Transene Al etchant type A (85% phosphoric acid, 5% acetic acid, 5% nitric acid, 5% water) at a temperature of about 30-40 C. The substrate is rinsed with water and dried. The photoresist is then stripped using an acetone spray and the substrate is dried and rolled.

Semiconductor deposition and patterning processes: A semiconductor level metal is vacuum deposited by unrolling and degassing the substrate in a vacuum deposition system. ZnO is RF sputtered onto the substrate in a plasma of 600 sccm Ar and 1 sccm O₂. The substrate is then rolled.

Patterning the semiconductor layer is accomplished according to the above common photoresist processes to apply photoresist, expose using the semiconductor level mask, and spray develop. The semiconductor level mask defines rectangular patterns that cover the thin film transistor at each crossing of the enable line and a data line.

The semiconductor layer is then patterned by unrolling, and spray etching the exposed ZnO with dilute HCl (0.1%) for 10 sec. The substrate is then rinsed in water and dried. The photoresist is then stripped using an acetone spray, and the substrate is dried and rolled.

At this point in the process, the substrate web is ready to be cut into individual backplanes with the enable lines being disconnected from the anodization bus in the process.

A display is formed by laminating onto the backplane an appropriate optically active material, such as a polymer dispersed liquid crystal, available from Xymox Technologies, Inc., or electrophoretic material (E Ink Corporation) and a transparent front electrode, e.g., indium tin oxide on PET. The display is operated by connecting a controller to the enable line bond pads and the data lines. To enable a row, a voltage of 10 V or greater is typically applied. While a given row is disabled, a voltage of −5 V is typically applied. The voltages applied to the data lines are chosen to apply the appropriate signal to the optically active material to achieve the desired optical state for each pixel.

### EXAMPLE 2

A monochrome display was fabricated on CORNING 1737 glass substrates using the design illustrated in FIG. 5. The minimum line width was 25 μm, with a pixel pitch of 1 mm. The experimental display included 12 rows and 16 columns. The 150 nm thick gate layer was formed from sputtered Al using standard photolithography and etching. That layer was anodized to form an Al₂O₃ gate insulator. A solution of tartaric acid in ethylene glycol was used for the anodization (see “Nanostructure and electrical properties of anodized Al gate insulator for thin film transistors,” T. Arai, Y. Hiromasu, and S. Tsuji, Mat. Res. Soc. Symp., Vol. 424, p. 37 (1991)), with an initial current density of 1.5 mA/cm² and a final voltage of 60 V, resulting in a specific capacitance of approximately 1000 pF/mm² and an oxide thickness of about 78 nm. A semiconductor layer of ZnO was RF sputtered in an Ar—O₂ plasma onto the substrate to a thickness of 15 nm. A source-drain metal layer of 100 nm of Al was sputtered onto the substrate and patterned by standard photolithography and liftoff. Polymer-dispersed liquid crystal film (model NCAP DP4 from Xymox Technologies Inc., 1277 Reamwood Avenue, Sunnyvale, Calif.) was laminated onto the backplane. This film includes a transparent conductive electrode that was used for the front electrode of the display. The resultant display was tested at frame rates of up to 50 frames/s using a row-enable voltage of 25 V, row-disable voltages of 0 V, and column data voltages of 0-25 V, all referenced to the transparent front electrode held at 0 V. The display was observed to successfully display images as designed.

The foregoing description of the various embodiments of the invention has been presented for the purposes of illustration and description. It is not intended to be exhaustive or to limit the invention to the precise form disclosed. Many modifications and variations are possible in light of the above teaching. For example, embodiments of the present invention may be implemented in a wide variety of applications. It is intended that the scope of the invention be limited not by this detailed description, but rather by the claims appended hereto.

What is claimed is:

1. A display backplane, comprising:
pixel electrodes arranged in an array of rows and columns on a substrate, the pixel electrodes comprising electrode extensions;
branchless data lines, each data line having a substantially constant width;
enable lines configured to carry signals that control current flow between the data lines and the pixel electrodes, each enable line having a substantially constant width and crossing a row of pixel electrodes and electrode extensions; and
storage capacitors at the crossings of the enable lines and the pixel electrodes.

2. The display backplane of claim 1, wherein the substrate comprises a flexible, polymeric substrate.

3. The display backplane of claim 1, wherein the backplane comprises variation in alignment of the enable lines and electrode extensions, the variation in alignment related to distortion of the substrate during fabrication.

4. The display backplane of claim 1, wherein a length of the electrode extensions is more than three times a width of the enable lines.

5. The display backplanes of claim 1, wherein each electrode extension extends in a direction of a column and along a major portion of a next pixel electrode in the column.

6. The display backplane of claim 1, further comprising transistors configured to allow the current flow between the data lines and the pixel electrodes responsive to the signals on the enable lines.

7. The display backplane of claim 6, wherein the transistors comprise ZnO.

8. The display backplane of claim 6, wherein the enable lines form anodized aluminum gates of the transistors.

9. The display backplane of claim 6, wherein:
the data lines form source or drain electrodes of the transistors; and
the electrode extensions form the drain or source electrodes of the transistors.

10. The display backplane of claim 6, wherein source or drain electrodes of the transistors have a width greater than the width of the enable lines.

11. A display backplane, comprising:
pixel electrodes including electrode extensions arranged on a substrate; and
enable lines configured to carry signals that control current flow to the pixel electrodes, each enable line crossing one or more electrode extensions, each electrode extension having a length greater than about three times a width of the enable line at a crossing of the enable line and the electrode extension.

12. The display backplane of claim 11, wherein the pixel electrodes are arranged in columns and an electrode extension of a first pixel electrode of a column extends along an edge of an adjacent pixel electrode of the column.

13. The display backplane of claim 11, wherein variation in alignment of the enable lines and the electrode extensions is related to distortion of the substrate during fabrication.

14. The display backplane of claim 11, wherein the substrate comprises a flexible, polymeric substrate.

15. The display backplane of claim 11, wherein the enable lines have substantially constant width.

16. The display backplane of claim 11, further comprising:
data lines crossing the enable lines; and
transistors configured to allow the current flow between the data lines and the pixel electrodes responsive to the signals on the enable lines.

17. The display backplane of claim 16, wherein the data lines have substantially constant width.

18. The display backplane of claim 11, wherein the enable lines cross the pixel electrodes.

19. The display backplane of claim 18, further comprising storage capacitors at crossings of the enable lines and the pixel electrodes.

20. A display backplane, comprising:
one or more rows of pixel electrodes arranged on a substrate;
data lines arranged substantially perpendicular to the row of pixel electrodes;
branchless enable lines, each enable line crossing the pixel electrodes of a row across a major dimension of the pixel electrodes; and
transistors configured to allow current flow between the data lines and pixel electrodes.

21. The display backplane of claim 20, wherein the substrate comprises a flexible substrate.

22. The display backplane of claim 20, wherein the substrate comprises a polymeric substrate.

23. The display backplane of claim 20, wherein the transistors comprise ZnO.

24. The display backplane of claim 20, wherein:
the enable lines form anodized aluminum gates of the transistors;
the data lines form source or drain electrodes of the transistors; and
the pixel electrodes form the drain or source electrodes of the transistors.

25. The display backplane of claim 20, wherein one or both of the source or drain electrodes of the transistors have a width greater than the width of the enable line.

26. The display backplane of claim 20, wherein the pixel electrodes include electrode extensions that form electrodes of the transistors.

27. A display backplane, comprising:
at least one column of pixel electrodes arranged on a substrate, the pixel electrodes having electrode extensions; and
enable lines configured to carry signals that control current flow to the pixel electrodes, each enable line crossing at least one electrode extension in the column, alignment of the enable lines with respect to the electrode extensions varying with position along the column of pixel electrodes.

28. The display backplane of claim 27, wherein the enable lines have a substantially constant width.

29. The display backplane of claim 27, wherein the substrate comprises a flexible substrate.

30. The display backplane of claim 27, wherein the variation in alignment is related to distortion of the substrate during fabrication of the display backplane.

31. The display backplane of claim 27, wherein each pixel electrode comprises an electrode extension that crosses an enable line.

32. The display backplane of claim 31, wherein a length of the electrode extension is related to alignment tolerance of the display backplane due to substrate distortion.

33. A display backplane, comprising:
pixel electrodes arranged in columns, each pixel electrode having a major portion and one or more electrode extensions, at least one pixel electrode in a column having an electrode extension that extends in the direction of the column along at least a portion of an edge of a major portion of a next pixel electrode in the column; and
enable lines that cross the electrode extensions, the enable lines configured to carry signals that control data flow between data lines and the pixel electrodes.

34. The display backplane of claim 33, wherein a length of each electrode extension is related to alignment tolerance of the display backplane due to substrate distortion.

35. The display backplane of claim 33, wherein variation in alignment with respect to the electrode extensions is related to distortion of the substrate during fabrication.

36. The display backplane of claim 33, wherein the substrate comprises a flexible substrate.

37. The display backplane of claim 33, wherein the enable lines have substantially constant width.

38. The display backplane of claim 33, further comprising:
data lines crossing the enable lines; and
transistors configured to allow current flow between the data line and the pixel electrodes responsive to the signals on the enable lines.

39. The display backplane of claim 38, wherein the data lines have substantially constant width.

40. The display backplane of claim 33, wherein the enable lines cross the pixel electrodes.

41. The display backplane of claim 40, further comprising storage capacitors at crossings of the enable lines and the pixel electrodes.

42. A display backplane, comprising:
pixel electrodes including electrode extensions arranged in a matrix on a substrate;
data lines;
enable lines crossing the pixel electrodes and the data lines;
one or more semiconductor regions, the semiconductor regions having areas larger than a pitch of the pixel electrodes, the semiconductor regions configured to allow current flow between the data lines and the pixel electrodes; and
storage capacitors at the crossings of the enable lines and the pixel electrodes, wherein voltages on the data lines are adjusted to compensate for crosstalk between the data lines.

43. The display backplane of claim 42, wherein the semiconductor regions comprise regional transistors having areas of channel formation controlled by signals on the enable lines.

45. A display device, comprising:
a backplane, comprising:
pixel electrodes including electrode extensions arranged in an array of rows and columns on a substrate;
data lines, each data line having a substantially constant width;
enable lines configured to carry signals that control data flow from the data lines to the pixel electrodes, each enable line having a substantially constant width and crossing a row of pixel electrodes and electrode extensions; and
storage capacitors at the crossings of the enable lines and the pixel electrodes; and
pixels comprising an optically active material coupled to the pixel electrodes.

46. The display device of claim 45, wherein the optically active material comprises a liquid crystal material.

47. The display device of claim 45, wherein the optically active material comprises an electrochromic material.

48. The display device of claim 45, wherein the optically active material comprises an electrophoretic material.

49. The display device of claim 45, wherein the display device comprises a reflective display device.

50. The display device of claim 45, wherein the pixels comprise color pixels and a common enable line crosses pixel electrodes of like color pixels.

51. The display of claim 45, wherein the pixels comprise color pixels and a common data line is associated with like color pixels.

52. A display device, comprising:
a backplane, comprising:
one or more rows of pixel electrodes arranged on a substrate;
data lines arranged substantially perpendicular to the row of pixel electrodes;
branchless enable lines, each enable line crossing the pixel electrodes of a row across a major dimension of the pixel electrodes; and
transistors configured to allow current flow between the data lines and pixel electrodes; and
pixels comprising an optically active material coupled to the pixel electrodes.

53. The display device of claim 52, wherein the optically active material comprises an electrophoretic material.
